(19) United States
(12) Patent Application Publication
(10) Pub. No.: US 2026/0143887 A1
(43) Pub. Date: May 21, 2026

(54) DISPLAY DEVICE

(71) Applicant: LG Display Co., Ltd., Seoul (KR)

(72) Inventors: Daeyoung SEO, Seoul (KR); ByungHyun LEE, Paju-si (KR); TaeYong KIM, Anyang-si (KR); Sumin LEE, Seoul (KR)

(73) Assignee: LG Display Co., Ltd., Seoul (KR)

(21) Appl. No.: 19/308,855

(22) Filed: Aug. 25, 2025

(30) Foreign Application Priority Data
Nov. 19, 2024 (KR) 10-2024-0164971

(51) Int. Cl. H10H 29/49; H10H 29/80

(52) U.S. Cl. CPC H10H 29/49; H10H 29/8325

(57) ABSTRACT

A display device can include a substrate, a first sub pixel circuit which is disposed on the substrate and includes a first driving transistor, a second sub pixel circuit which is disposed on the substrate and includes a second driving transistor, and a plurality of light emitting diodes which is disposed on the first sub pixel circuit and the second sub pixel circuit and includes a plurality of first electrodes and a second electrode. Any one of the plurality of first electrodes is electrically connected to the first driving transistor and another one of the plurality of first electrodes is electrically connected to the second driving transistor. Therefore, a dark spot defect of the sub pixel due to the defect of the driving transistor can be minimized or prevented.

### CROSS-REFERENCE TO RELATED APPLICATIONS

This application claims priority to Korean Patent Application No. 10-2024-0164971 filed on November 19, 2024, in the Korean Intellectual Property Office, the entire disclosure of which is hereby expressly incorporated by reference into the present application.

### BACKGROUND

### FIELD

The present disclosure relates to a display device, and more particularly to a display device in which a dark spot defect of the sub pixel which can be caused by the defect of the driving transistor is minimized or prevented.

### Discussion of the Related Art

As display devices which are used for a monitor of a computer, a television, or a cellular phone, there are an organic light emitting display device (OLED) which is a self-emitting device and a liquid crystal display device (LCD) which requires a separate light source.

An applicable range of the display device is diversified into personal digital assistants as well as monitors of computers and televisions and a display device with a large display area and a reduced volume and weight is being studied.

Further, a display device including a light emitting diode (LED) is attracting attention as a next generation display device. Since the LED is formed of an inorganic material, rather than an organic material, reliability is excellent so that a lifespan thereof is longer than that of the liquid crystal display device or the organic light emitting display device. Further, the LED has a fast lighting speed, excellent luminous efficiency, and a strong impact resistance so that a stability is excellent and an image having a high luminance can be displayed.

### SUMMARY OF THE DISCLOSURE

An object to be achieved by the present disclosure is to provide a display device in which a high luminance is implemented by placing two light emitting diodes in one sub pixel.

Another object to be achieved by the present disclosure is to provide a display device in which a dark spot defect of the sub pixel which can be caused by the defect of the driving transistor is minimized or prevented.

Objects of the present disclosure are not limited to the above-mentioned objects, and other objects, which are not mentioned above, can be clearly understood by those skilled in the art from the following descriptions.

According to an aspect of the present disclosure, a display device includes a substrate, a first sub pixel circuit which is disposed on the substrate and includes a first driving transistor, a second sub pixel circuit which is disposed on the substrate and includes a second driving transistor, and a plurality of light emitting diodes which is disposed on the first sub pixel circuit and the second sub pixel circuit and includes a plurality of first electrodes and a second electrode. Any one of the plurality of first electrodes is electrically connected to the first driving transistor and another one of the plurality of first electrodes is electrically connected to the second driving transistor.

According to an aspect of the present disclosure, a display device includes a substrate in which a plurality of sub pixels is defined, a first driving transistor and a second driving transistor which are disposed on the substrate in each of the plurality of sub pixels, and a first light emitting diode and a second light emitting diode which are disposed on the first driving transistor and the second driving transistor in each of the plurality of sub pixels and emit the same color light. Each of the first driving transistor and the second driving transistor is electrically connected to both the first light emitting diode and the second light emitting diode. Therefore, the dark spot defect of the sub pixel due to the defect of the driving transistor can be minimized.

Other detailed matters of the example embodiments of the present disclosure are included in the detailed description and the drawings.

According to the example embodiments of the present disclosure, two driving transistors are connected to one light emitting diode so that even though any one of the two driving transistors is defective, the other light emitting diode is driven to light the light emitting diode.

According to the example embodiments of the present disclosure, a dark spot defect of the sub pixel due to the defect of the driving transistor can be minimized or prevented.

According to the example embodiments of the present disclosure, two light emitting diodes disposed in one sub pixel share two driving transistors so that even though any one of two driving transistors is defective, the other one is driven to light both the light emitting diodes to implement high luminance.

According to the example embodiments of the present disclosure, a display device with a high luminance is implemented to drive the display device at a low power in terms of reduction in power consumption.

The effects according to the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic diagram of a display device according to an example embodiment of the present disclosure;

FIG. 2 is a circuit diagram of a sub pixel of a display device according to an example embodiment of the present disclosure;

FIG. 3 is a plan view of a pixel of a display device according to an example embodiment of the present disclosure; and

FIG. 4 is a cross-sectional view taken along IV-IV’ of FIG. 3.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the disclosure. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components. Therefore, a first component to be mentioned below can be a second component in a technical concept of the present disclosure. Further, the term “can” fully encompasses all the meanings and coverages of the term “may” and vice versa.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to example embodiments of the present disclosure will be described in detail with reference to accompanying drawings. All the components of each display device/apparatus according to all embodiments of the present disclosure are operatively coupled and configured.

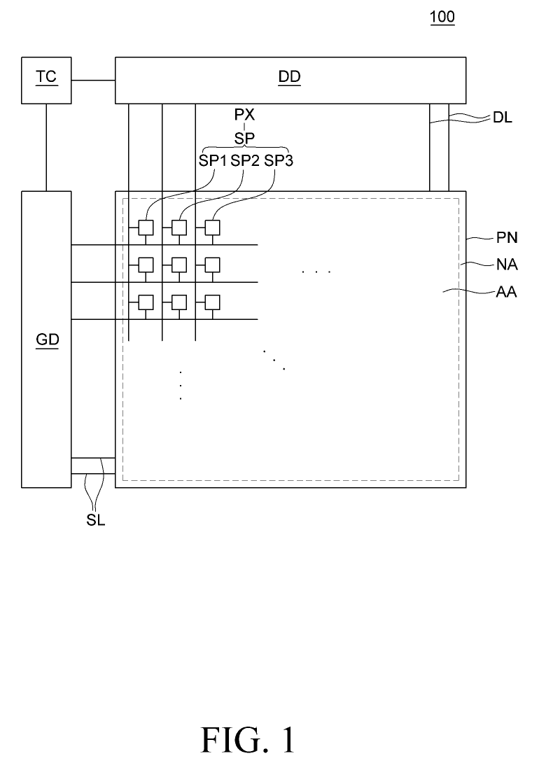

FIG. 1 is a schematic diagram of a display device according to an example embodiment of the present disclosure. In FIG. 1, for the convenience of description, among various components of a display device 100, a display panel PN, a gate driver GD, a data driver DD, and a timing controller TC are illustrated.

Referring to FIG. 1, the display device 100 includes a display panel PN including a plurality of sub pixels SP, a gate driver GD and a data driver DD which supply various signals to the display panel PN, and a timing controller TC which controls the gate driver GD and the data driver DD.

A driver, such as a gate driver GD, a data driver DD, and a timing controller TC, can be connected to the display panel PN in various ways. For example, the gate driver GD can be mounted in the non-active area NA in a gate in panel (GIP) manner or mounted between the plurality of sub pixels SP in the active area AA in a gate in active area (GIA) manner.

The display panel PN is a configuration which displays images to the user and includes the plurality of sub pixels SP. In the display panel PN, the plurality of scan lines SL and the plurality of data lines DL intersect each other and the plurality of sub pixels SP is connected to the scan lines SL and the data lines DL, respectively. In addition, each of the plurality of sub pixels SP can be connected to a high potential power line, a low potential power line, and a reference line.

In the display panel PN, an active area AA and a non-active area NA enclosing the active area AA can be defined.

The active area AA is an area in which images are displayed in the display device 100. In the active area AA, a plurality of sub pixels SP which configures a plurality of pixels and a circuit for driving the plurality of sub pixels SP can be disposed. The plurality of sub pixels SP is a minimum unit which configures the active area AA and n sub pixels SP form one pixel. In each of the plurality of sub pixels SP, a light emitting diode and a thin film transistor for driving the light emitting diode can be disposed. The plurality of light emitting diodes can be defined in different manners depending on the type of the display panel PN. For example, when the display panel PN is an inorganic light emitting display panel, the light emitting diode can be a light emitting diode (LED) or a micro light emitting diode (micro-LED).

In the active area AA, a plurality of signal lines which transmits various signals to the plurality of sub pixels SP is disposed. For example, the plurality of signal lines can include a plurality of data lines DL which supplies a data voltage to each of the plurality of sub pixels SP and a plurality of scan lines which supplies a gate voltage to each of the plurality of sub pixels SP. The plurality of scan lines SL extends to one direction in the active area AA to be connected to the plurality of sub pixels SP and the plurality of data lines DL extends to a direction different from the one direction in the active area AA to be connected to the plurality of sub pixels SP. In addition, in the active area AA, a low potential power line and a high potential power line can be further disposed, but are not limited thereto.

In the non-active area NA, images are not displayed, but a link line which transmits a signal to the sub pixel SP of the active area AA, a pad electrode, or a driving IC, such as a gate driver IC or a data driver IC, can be disposed.

The display panel PN includes a plurality of pixels which is formed by a plurality of sub pixels SP. Each of the plurality of sub pixels SP includes a light emitting diode LED and a pixel circuit to independently emit light. One pixel can include a first sub pixel SP1, a second sub pixel SP2, and a third sub pixel SP3. For example, one pixel can be configured by one pair of first sub pixels SP1, one pair of second sub pixels SP2, and one pair of third sub pixels SP3. At this time, the first sub pixel SP1 is a red sub pixel, the second sub pixel SP2 is a green sub pixel, and the third sub pixel SP3 is a blue sub pixel, but they are not limited thereto.

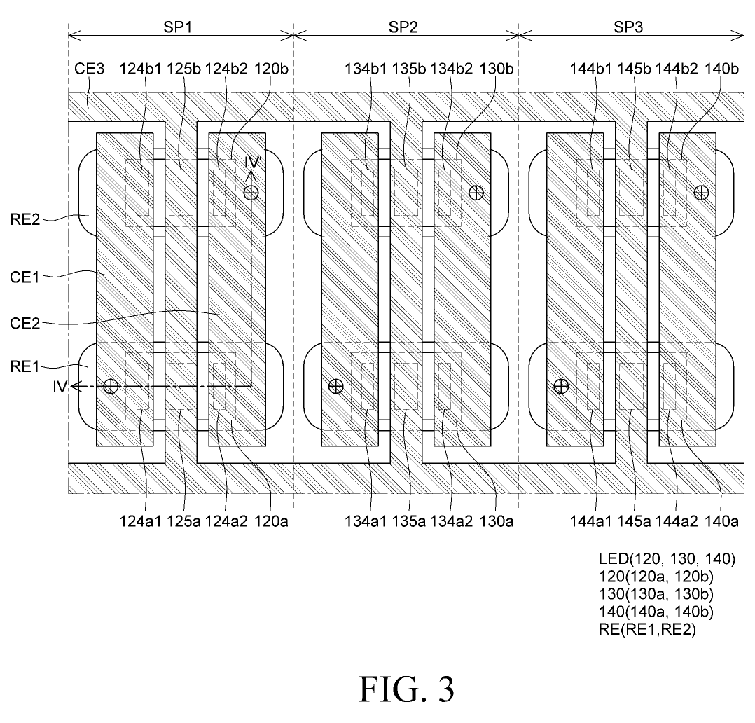

A plurality of light emitting diodes can be disposed in the plurality of sub pixels SP. For example, as illustrated in FIG. 3 to be described below, the plurality of light emitting diodes LED can include a first light emitting diode, a second light emitting diode, and a third light emitting diode. The first light emitting diode 120 is disposed in the first sub pixel SP1, the second light emitting diode 130 is disposed in the second sub pixel SP2, and the third light emitting diode 140 can be disposed in the third sub pixel SP3. For example, the first light emitting diode 120 is a red light emitting diode, the second light emitting diode 130 is a green light emitting diode, and the third light emitting diode 140 can be a blue light emitting diode. However, other variations are possible.

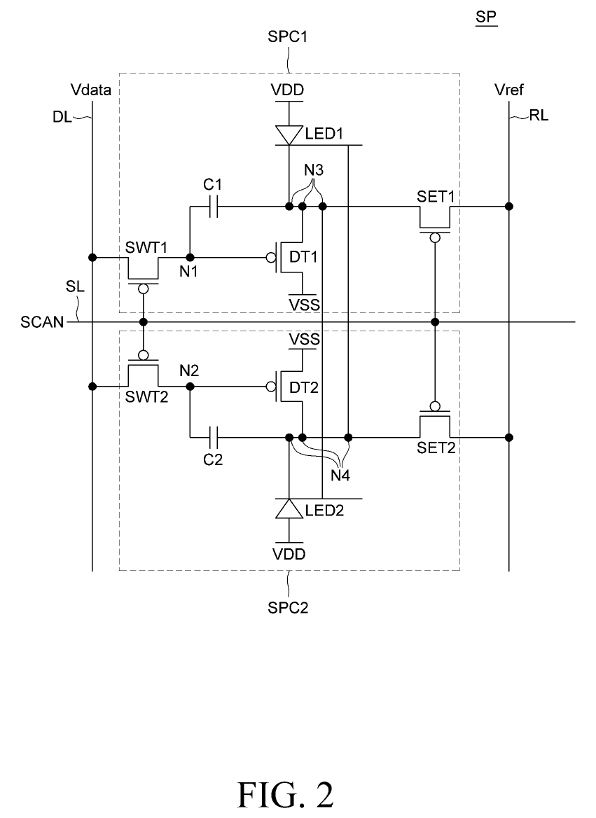

FIG. 2 is a circuit diagram of a sub pixel of a display device according to an example embodiment of the present disclosure.

Referring to FIG. 2, the plurality of sub pixels SP can include a first sub pixel circuit SPC1 and a second sub pixel circuit SPC2. For example, each of the plurality of sub pixels SP of the display device can have the sub pixel configuration of FIG. 2.

The first sub pixel circuit SPC1 can include a first light emitting diode LED1, a first driving transistor DT1, a first sensing transistor SET1, a first switching transistor SWT1, and a first capacitor C1.

The second sub pixel circuit SPC2 can include a second light emitting diode LED2, a second driving transistor DT2, a second sensing transistor SET2, a second switching transistor SWT2, and a second capacitor C2.

For example, each of the first sub pixel circuit SPC1 and the second sub pixel circuit SPC2 can have a 3T1C structure including three transistors and one capacitor, but is not limited thereto.

Each of the plurality of transistors included in the first sub pixel circuit SPC1 and the second sub pixel circuit SPC2 includes a gate electrode, a source electrode, and a drain electrode.

At this time, at least some of the plurality of transistors included in the first sub pixel circuit SPC1 and the second sub pixel circuit SPC2 can be an N-type transistor or a P-type transistor. For example, since in a P-type thin film transistor, holes flow from the source electrode to the drain electrode, the current flows from the source electrode to the drain electrode. Since in the N-type thin film transistor, electrons flow from the source electrode to the drain electrode, the current flows from the drain electrode to the source electrode. In the case of the P-type transistor, a low level voltage of each driving signal refers to a voltage which turns on transistors and a high level voltage of each driving signal can refer to a voltage which turns off the transistors.

In the display device according to the example embodiment of the present disclosure, it is assumed that the first driving transistor DT1, the first sensing transistor SET1, the first switching transistor SWT1, the second driving transistor DT2, the second sensing transistor SET2, and the second switching transistor SWT2 are P-type transistors. However, the present disclosure is not limited thereto.

In the meantime, the first sub pixel circuit SPC1 and the second sub pixel circuit SPC2 can share the scan line SL, the data line DL, and the reference line RL.

Specifically, the first driving transistor DT1 of the first sub pixel circuit SPC1 can control a driving current applied to the first light emitting diode LED1 and the second light emitting diode LED2 according to the source-gate voltage Vsg. The first driving transistor DT1 includes a gate electrode connected to the drain electrode of the first switching transistor SWT1, a source electrode connected to a cathode electrode of the first light emitting diode LED1 and a cathode electrode of the second light emitting diode LED2, and a drain electrode. The drain electrode is connected to a low potential power voltage line to which a low potential power voltage VSS is supplied.

The second driving transistor DT2 of the second sub pixel circuit SPC2 can control a driving current applied to the second light emitting diode LED2 according to the source-gate voltage Vsg. The second driving transistor DT2 includes a gate electrode connected to the drain electrode of the second switching transistor SWT2, a source electrode connected to a cathode electrode of the first light emitting diode LED1 and a cathode electrode of the second light emitting diode LED2, and a drain electrode. The drain electrode is connected to a low potential power voltage line to which a low potential power voltage VSS is supplied.

The first switching transistor SWT1 of the first sub pixel circuit SPC1 can apply a data voltage Vdata which is applied from the data line DL to a first node N1. The first switching transistor SWT1 can include a source electrode connected to the data line DL, a drain electrode connected to the first node N1, and a gate electrode connected to a scan line SL to which a scan signal SCAN is applied. For example, the first switching transistor SWT1 can be turned on or turned off by the scan signal SCAN. Accordingly, the first switching transistor SWT1 can apply a data voltage Vdata from the data line DL to the first node N1, in response to a low level of scan signal SCAN which is a turn-on level.

The second switching transistor SWT2 of the second sub pixel circuit SPC2 can apply a data voltage Vdata which is applied from the data line DL to a second node N2. The second switching transistor SWT2 can include a source electrode connected to the data line DL, a drain electrode connected to the second node N2, and a gate electrode connected to a scan line SL to which a scan signal SCAN is applied. For example, the second switching transistor SWT2 can be turned on or turned off by the scan signal SCAN. Accordingly, the second switching transistor SWT2 can apply a data voltage Vdata from the data line DL to the second node N2, in response to a low level of scan signal SCAN which is a turn-on level.

In the meantime, the first switching transistor SWT1 and the second switching transistor SWT2 can share the scan line SL. Therefore, the first switching transistor SWT1 and the second switching transistor SWT2 can be simultaneously turned on or turned off according to the scan signal SCAN of the scan line SL, but are not limited thereto.

The first sensing transistor SET1 of the first sub pixel circuit SPC1 can apply the reference voltage Vref applied from the reference line RL to the third node N3. The first sensing transistor SET1 can include a source electrode connected to the reference line RL, a drain electrode connected to the third node N3, and a gate electrode connected to a scan line SL to which a scan signal SCAN is applied. For example, the first sensing transistor SET1 can be turned on or turned off by the scan signal SCAN. Therefore, the first sensing transistor SET1 can apply the reference voltage Vref from the reference line RL to the third node N3 in response to a low level of scan signal SCAN which is a turn-on level.

The second sensing transistor SET2 of the second sub pixel circuit SPC2 can apply the reference voltage Vref applied from the reference line RL to a fourth node N4. The second sensing transistor SET2 can include a source electrode connected to the reference line RL, a drain electrode connected to the fourth node N4, and a gate electrode connected to the scan line SL to which the scan signal SCAN is applied. For example, the second sensing transistor SET2 can be turned on or turned off by the scan signal SCAN. Therefore, the second sensing transistor SET2 can apply the reference voltage from the reference line RL to the fourth node N4 in response to a low level of scan signal SCAN which is a turn-on level.

In the meantime, the first sensing transistor SET1 and the second sensing transistor SET2 can share the scan line SL. Therefore, the first sensing transistor SET1 and the second sensing transistor SET2 can be simultaneously turned on or turned off according to the scan signal SCAN of the scan line SL, but are not limited thereto.

The first capacitor C1 of the first sub pixel circuit SPC1 can include a first electrode connected to the first node N1 and a second electrode connected to the third node N3. For example, the first electrode of the first capacitor C1 is connected to the gate electrode of the first driving transistor DT1 and the second electrode of the first capacitor C1 is connected to the source electrode of the first driving transistor DT1. Accordingly, the first capacitor C1 maintains a potential difference between the gate electrode and the source electrode of the first driving transistor DT1 while the first light emitting diode LED1 emits light to supply a constant driving current to the first light emitting diode LED1.

The second capacitor C2 of the second sub pixel circuit SPC2 can include a first electrode connected to the second node N2 and a second electrode connected to the fourth node N4. For example, the first electrode of the second capacitor C2 is connected to the gate electrode of the second driving transistor DT2 and the second electrode of the second capacitor C2 is connected to the source electrode of the second driving transistor DT2. Accordingly, the second capacitor C2 maintains a potential difference between the gate electrode and the source electrode of the second driving transistor DT2 while the second light emitting diode LED2 emits light to supply a constant driving current to the second light emitting diode LED2.

The first light emitting diode LED1 includes an anode electrode connected to a high potential power line to which a high potential power voltage VDD is supplied and a cathode electrode connected to the third node N3 and the fourth node N4. For example, the cathode electrode of the first light emitting diode LED1 can be connected to both the first driving transistor DT1 and the second driving transistor DT2. Therefore, the first light emitting diode LED1 is supplied with the driving current from the first driving transistor DT1 and the second driving transistor DT2 to emit light.

The second light emitting diode LED2 includes an anode electrode connected to a high potential power line to which a high potential power voltage VDD is supplied and a cathode electrode connected to the third node N3 and the fourth node N4. For example, the cathode electrode of the second light emitting diode LED2 can be connected to both the first driving transistor DT1 and the second driving transistor DT2. Therefore, the second light emitting diode LED2 is supplied with the driving current from the first driving transistor DT1 and the second driving transistor DT2 to emit light.

For example, the first light emitting diode LED1 and the second light emitting diode LED2 can share the first driving transistor DT1 and the second driving transistor DT2.

In other words, the first light emitting diode LED1 and the second light emitting diode LED2 can be connected to both the first driving transistor DT1 and the second driving transistor DT2.

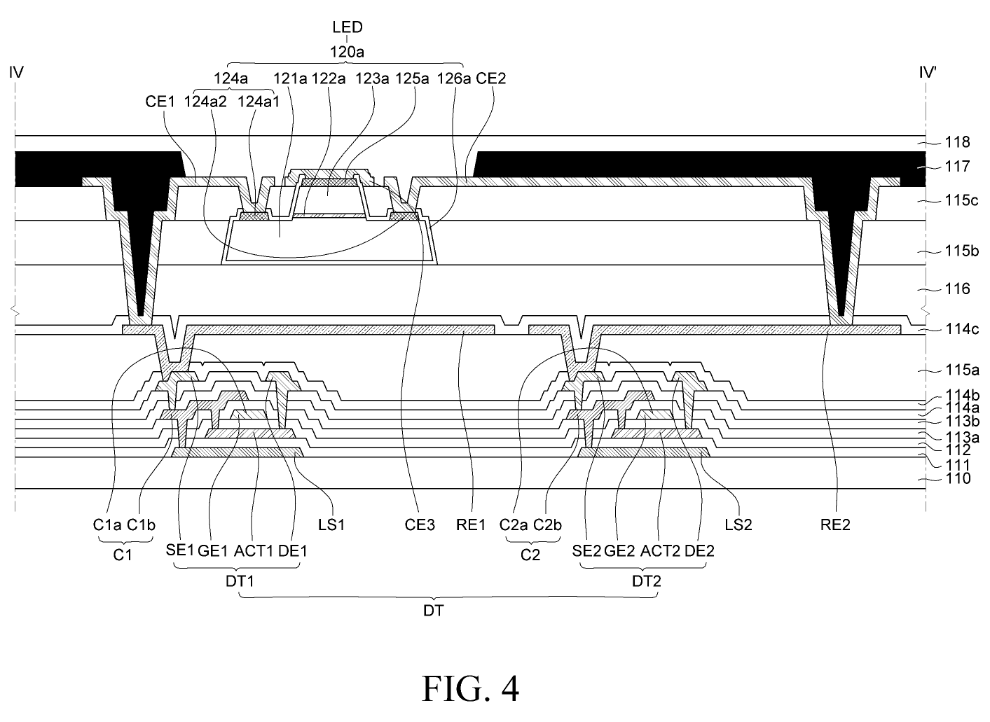

FIG. 3 is a plan view of a pixel of a display device according to an example embodiment of the present disclosure. FIG. 4 is a cross-sectional view taken along IV-IV’ of FIG. 3. In FIG. 3, only a reflective electrode RE, a light emitting element LED, a first connection electrode CE1, a second connection electrode CE2, and a third connection electrode CE3, among various configurations of the display device 100, are illustrated. According to the actual structure, the first connection electrode CE1, the second connection electrode CE2, and the third connection electrode CE3 are disposed on the light emitting diode LED, but for the convenience of description, the light emitting diode LED is illustrated with a dashed line. Further, FIG. 4 illustrates a cross-sectional view of the first sub pixel SP1 as an example and the cross-sectional views of the second sub pixel SP2 and the third sub pixel SP3 are also substantially the same as the cross-sectional view of the first sub pixel SP1.

First, referring to FIGS. 1 and 4, the display panel PN includes a plurality of pixels PX which is formed by a plurality of sub pixels SP. Each of the plurality of sub pixels SP includes a light emitting diode LED and a sub pixel circuit to independently emit light. One pixel PX can include a first sub pixel SP1, a second sub pixel SP2, and a third sub pixel SP3. For example, one pixel PX can include one first sub pixel SP1, one second sub pixel SP2, and one third sub pixel SP3. At this time, the first sub pixel SP1 is a red sub pixel, the second sub pixel SP2 is a green sub pixel, and the third sub pixel SP3 is a blue sub pixel, but they are not limited thereto.

A plurality of reflection electrodes RE which is spaced apart from each other can be disposed on the plurality of sub pixels SP. The plurality of reflective electrodes RE electrically connects the light emitting diode LED to the first driving transistor DT1 and the second driving transistor DT2 and can serve as a reflector which reflects light emitted from the light emitting diode LED toward the top of the light emitting diode LED. The plurality of reflective electrodes RE is formed of a conductive material having the excellent reflecting property to reflect light emitted from the light emitting diode LED toward the upper portion of the light emitting diode LED.

The plurality of reflective electrodes RE can include a plurality of first reflective electrodes RE1 and a plurality of second reflective electrodes RE2. The plurality of first reflective electrodes RE1 can electrically connect the first driving transistor DT1 and the light emitting diode LED. For example, each of the plurality of first reflective electrodes RE1 can be connected to the first driving transistor DT1. Further, each of the plurality of first reflective electrodes RE1 can be electrically connected to 1-1-th electrodes 124a1 and 124b1 of the light emitting diode LED through the first connection electrode CE1.

Specifically, one of the plurality of first reflective electrodes RE1 can be connected to a 1-1-th electrode 124a1 of a 1-1-th light emitting diode 120a through the first connection electrode CE1. At this time, as it will be described below, a 1-1-th light emitting diode 120a as the first light emitting diode and a 1-2-th light emitting diode 120b as the second light emitting diode share the first connection electrode CE1 so that one first reflective electrode RE1 can also be connected to the 1-1-th electrode 124b1 of the 1-2-th light emitting diode 120b through the first connection electrode CE1. Accordingly, one first reflective electrode RE1 can connect the 1-1-th light emitting diode 120a and the 1-2-th light emitting diode 120b which emit the same color light to the same first driving transistor DT1.

The plurality of second reflective electrodes RE2 can electrically connect the second driving transistor DT2 and the light emitting diode LED. For example, each of the plurality of second reflective electrodes RE2 can be connected to the second driving transistor DT2. Further, each of the plurality of second reflective electrodes RE2 can be electrically connected to 1-2-th electrodes 124a2 and 124b2 of the light emitting diode LED through the second connection electrode CE2.

Specifically, one of the plurality of second reflective electrodes RE2 can be connected to a 1-2-th electrode 124a2 of a 1-1-th light emitting diode 120a through the second connection electrode CE2. A 1-1-th light emitting diode 120a and a 1-2-th light emitting diode 120b share the second connection electrode CE2 so that one second reflective electrode RE2 can also be connected to the 1-2-th electrode 124b2 of the 1-2-th light emitting diode 120b through the second connection electrode CE2. Accordingly, one second reflective electrode RE2 can connect the 1-1-th light emitting diode 120a and the 1-2-th light emitting diode 120b which emit the same color light to the same second driving transistor DT2.

The plurality of light emitting diodes LED can be disposed on the plurality of reflective electrodes RE. Specifically, the plurality of light emitting diodes LED can include a first light emitting diode 120 disposed in the first sub pixel SP1, a second light emitting diode 130 disposed in the second sub pixel SP2, and a third light emitting diode 140 which is disposed in the third sub pixel SP3.

The first light emitting diode 120 can be disposed in the first sub pixel SP1. The first light emitting diode 120 can include a 1-1-th light emitting diode 120a and a 1-2-th light emitting diode 120b which emit the same color light.

The second light emitting diode 130 can be disposed in the second sub pixel SP2. The second light emitting diode 130 can include a 2-1-th light emitting diode 130a and a 2-2-th light emitting diode 130b which emit the same color light.

The third light emitting diode 140 can be disposed in the third sub pixel SP3. The third light emitting diode 140 can include a 3-1-th light emitting diode 140a and a 3-2-th light emitting diode 140b which emit the same color light.

For example, the first light emitting diode 120 is a red light emitting diode, the second light emitting diode 130 is a green light emitting diode, and the third light emitting diode 140 can be a blue light emitting diode.

For example, two red light emitting diodes are disposed in the first sub pixel SP1, two green light emitting diodes are disposed in the second sub pixel SP2, and two blue light emitting diodes can be disposed in the third sub pixel SP3. At this time, two light emitting diodes LED which are disposed in the same sub pixel SP to emit the same color light can share two different driving transistors DT. For example, two light emitting diodes LED which are disposed in the same sub pixel SP to emit the same color light are connected to the same driving transistor DT to be simultaneously lit up. This will be described in detail with reference to FIG. 4 to be described below.

In the meantime, in FIG. 4, only the cross-section regarding the 1-1-th light emitting diode 120a has been illustrated. However, a 1-2-th light emitting diode 120b, a 2-1-th light emitting diode 130a, a 2-2-th light emitting diode 130b, a 3-1-th light emitting diode 140a, and a 3-2-th light emitting diode 140b can also be electrically connected to two different driving transistors DT, for example, the first driving transistor DT1 and the second driving transistor DT2, in the same manner. A redundant description will be omitted or may be briefly provided.

For example, in FIG. 3, the first light emitting diode 120, the second light emitting diode 130, and the third light emitting diode 140 are illustrated to have the same shape, but the first light emitting diode 120, the second light emitting diode 130, and the third light emitting diode 140 can have different shapes. For example, a planar shape of the first light emitting diode 120 can be a circular shape and a planar shape of the second light emitting diode 130 and the third light emitting diode 140 can be an oval shape. At this time, the second light emitting diode 130 and the third light emitting diode 140 can have different sizes to have different oval shapes. In the meantime, a major axis direction of the second light emitting diode 130 and the third light emitting diode 140 can be the same, but the present disclosure is not limited thereto.

The 1-1-th light emitting diode 120a can include a first semiconductor layer 121a, an emission layer 122a, a second semiconductor layer 123a, a 1-1-th electrode 124a1, a 1-2-th electrode 124a2, a second electrode 125a, and a passivation film 126a. At this time, a planar shape of the first semiconductor layer 121a of the 1-1-th light emitting diode 120a can be a circular shape and a planar shape of the second semiconductor layer 123a can be an oval shape which is the same as the top surface of the second electrode 125a. The planar shapes of the 1-1-th electrode 124a1 and the 1-2-th electrode 124a2 have a truncated oval shape, for example, a semi-oval shape, but are not limited thereto.

The shape and the configuration of the 1-2-th light emitting diode 120b can be substantially the same as the shape and the configuration of the 1-1-th light emitting diode 120a. Specifically, the 1-2-th light emitting diode 120b can include a first semiconductor layer, an emission layer, a second semiconductor layer, a 1-1-th electrode 124b1, a 1-2-th electrode 124b2, a second electrode 125b, and a passivation film. At this time, a planar shape of the first semiconductor layer of the 1-2-th light emitting diode 120b can be a circular shape and a planar shape of the second semiconductor layer can be an oval shape which is the same as the top surface of the second electrode 125b. The planar shapes of the 1-1-th electrode 124b1 and the 1-2-th electrode 124b2 can have a truncated oval shape, for example, a semi-oval shape, but are not limited thereto.

For example, in the display device 100 according to the example embodiment of the present disclosure, the first light emitting diode 120, the second light emitting diode 130, and the third light emitting diode 140 are configured to have different shapes, respectively, to distinguish the plurality of light emitting diodes LED. For example, when the light emitting diode LED is self-assembled, the plurality of light emitting diodes LED is formed to have different shapes to be self-assembled in a position corresponding to each of the plurality of sub pixels SP. However, the shapes of the plurality of light emitting diodes LED are illustrative, so that it is not limited thereto.

A plurality of first connection electrodes CE1, a plurality of second connection electrodes CE2, and a plurality of third connection electrodes CE3 can be disposed on the plurality of light emitting diodes LED. Each of the plurality of first connection electrodes CE1 can be connected to the 1-1-th electrodes 124a1 and 124b1 of the plurality of light emitting diodes LED and each of the plurality of second connection electrodes CE2 can be connected to the 1-2-th electrodes 124a2 and 124b2. Each of the plurality of third connection electrodes CE3 can be connected to the second electrodes 125a and 125b.

For example, the first connection electrode CE1 and the second connection electrode CE2 can be disposed in the plurality of sub pixels SP, but the third connection electrode CE3 can be commonly disposed in the plurality of sub pixels SP. In other words, the first connection electrode CE1 and the second connection electrode CE2 are disposed in the first sub pixel SP1, the second sub pixel SP2, and the third sub pixel SP3, but the first sub pixel SP1, the second sub pixel SP2, and the third sub pixel SP3 can share the third connection electrode CE3. However, the example embodiment of the present disclosure is not limited thereto. Specifically, the first connection electrode CE1 can electrically connect the 1-1-th electrodes 124a1 and 124b1 of two light emitting diodes LED which emit the same color light. For example, one first connection electrode CE1 can connect the 1-1-th electrode 124a1 of the 1-1-th light emitting diode 120a and the 1-1-th electrode 124b1 of the 1-2-th light emitting diode 120b in the first sub pixel SP1. Another first connection electrode CE1 can connect the 1-1-th electrode 134a1 of the 2-1-th light emitting diode 130a and the 1-1-th electrode 134b1 of the 2-2-th light emitting diode 130b in the second sub pixel SP2. Further, the third first connection electrode CE1 can connect the 1-1-th electrode 144a1 of the 3-1-th light emitting diode 140a and the 1-1-th electrode 144b1 of the 3-2-th light emitting diode 140b in the third sub pixel SP3.

For example, the 1-1-th light emitting diode 120a can share one first connection electrode CE1 with the 1-2-th light emitting diode 120b. The 2-1-th light emitting diode 130a can share another first connection electrode CE1 with the 2-2-th light emitting diode 130b. Further, the 3-1-th light emitting diode 140a can share the third first connection electrode CE1 with the 3-2-th light emitting diode 140b.

The second connection electrode CE2 can electrically connect the 1-2-th electrodes 124a2 and 124b2 of two light emitting diodes LED which emit the same color light. For example, one second connection electrode CE2 can connect the 1-2-th electrode 124a2 of the 1-1-th light emitting diode 120a and the 1-2-th electrode 124b2 of the 1-2-th light emitting diode 120b in the first sub pixel SP1. Another second connection electrode CE2 can connect the 1-2-th electrode 134a2 of the 2-1-th light emitting diode 130a and the 1-2-th electrode 134b2 of the 2-2-th light emitting diode 130b in the second sub pixel SP2. Further, the third second connection electrode CE2 can connect the 1-2-th electrode 144a2 of the 3-1-th light emitting diode 140a and the 1-2-th electrode 144b2 of the 3-2-th light emitting diode 140b in the third sub pixel SP3.

For example, the 1-1-th light emitting diode 120a can share one second connection electrode CE2 with the 1-2-th light emitting diode 120b. The 2-1-th light emitting diode 130a can share another second connection electrode CE2 with the 2-2-th light emitting diode 130b. Further, the 3-1-th light emitting diode 140a can share the third second connection electrode CE2 with the 3-2-th light emitting diode 140b.

In other words, the 1-1-th electrode 124a1 of the first electrodes 124a of the 1-1-th light emitting diode 120a is connected to one first reflective electrode RE1 through one first connection electrode CE1. The 1-2-th electrode 124a2 is connected to one second reflective electrode RE2 through one second connection electrode CE2. Therefore, the 1-1-th light emitting diode 120a can be connected to different driving transistors DT.

Likewise, the 1-1-th electrode 124b1 of the first electrodes 124b of the 1-2-th light emitting diode 120b is connected to one first reflective electrode RE1 through one first connection electrode CE1. The 1-2-th electrode 124b2 is connected to one second reflective electrode RE2 through one second connection electrode CE2. Therefore, the 1-2-th light emitting diode 120b can be connected to different driving transistors DT.

In the second sub pixel SP2, the 1-1-th electrode 134a1 of the first electrodes 134a of the 2-1-th light emitting diode 130a is connected to another first reflective electrode RE1 through another first connection electrode CE1. The 1-2-th electrode 134a2 is connected to another second reflective electrode RE2 through another second connection electrode CE2. Therefore, the 2-1-th light emitting diode 130a can be connected to different driving transistors DT.

Likewise, the 1-1-th electrode 134b1 of the first electrodes 134b of the 2-2-th light emitting diode 130b is connected to another first reflective electrode RE1 through another first connection electrode CE1. The 1-2-th electrode 134b2 is connected to another second reflective electrode RE2 through another second connection electrode CE2. Therefore, the 2-2-th light emitting diode 130b can be connected to different driving transistors DT.

In the third sub pixel SP3, the 1-1-th electrode 144a1 of the first electrodes 144a of the 3-1-th light emitting diode 140a is connected to the third first reflective electrode RE1 through the third first connection electrode CE1. The 1-2-th electrode 144a2 is connected to the third second reflective electrode RE2 through the third second connection electrode CE2. Therefore, the 3-1-th light emitting diode 140a can be connected to different driving transistors DT.

Likewise, the 1-1-th electrode 144b1 of the first electrodes 144b of the 3-2-th light emitting diode 140b is connected to the third first reflective electrode RE1 through the third first connection electrode CE1. The 1-2-th electrode 144b2 is connected to the third second reflective electrode RE2 through the third second connection electrode CE2. Therefore, the 3-2-th light emitting diode 140b can be connected to different driving transistors DT.

Accordingly, even though any one of the driving transistors DT is defective, the light emitting diode LED can be lit up by the other driving transistor. Further, the first connection electrode CE1 and the second connection electrode CE2 electrically connect two light emitting diodes LED which emit same color so that two light emitting diodes LED can be simultaneously lit up. This will be described in detail with reference to FIG. 4 to be described below.

Next, in the display panel PN of the display device 100 according to the example embodiment of the present disclosure, in each of the plurality of sub pixels SP, a substrate 110, a buffer layer 111, a gate insulating layer 112, a first interlayer insulating layer 113a, a second interlayer insulating layer 113b, a first passivation layer 114a, a second passivation layer 114b, a third passivation layer 114c, a first planarization layer 115a, a second planarization layer 115b, a third planarization layer 115c, an adhesive layer 116, a bank 117, a capping layer 118, a first driving transistor DT1, a second driving transistor DT2, a first switching transistor SWT1, a second switching transistor SWT2, a light emitting diode LED, a first reflective electrode RE1, a second reflective electrode RE2, a first light shielding layer LS1, a second light shielding layer LS2, a first connection electrode CE1, a second connection electrode CE2, a third connection electrode CE3, a first capacitor C1, and a second capacitor C2 can be disposed.

First, the substrate 110 is a component for supporting various components included in the display device 100 and can be formed of an insulating material. For example, the substrate 110 can be formed of glass or resin. Further, the substrate 110 can be configured to include a polymer or plastics or can be formed of a material having flexibility.

The first light shielding layer LS1 and the second light shielding layer LS2 can be disposed in each of the plurality of sub pixels SP on the substrate 110. The first light shielding layer LS1 is disposed below a first active layer ACT1 of the first driving transistor DT1 to block light which is incident to the first active layer ACT1 to minimize the leakage current. The second light shielding layer LS2 is disposed below a second active layer ACT2 of the second driving transistor DT2 to block light which is incident to the second active layer ACT2 to minimize the leakage current. The first light shielding layer LS1 and the second light shielding layer LS2 can be configured by an opaque conductive material such as copper (Cu), aluminum (Al), molybdenum (Mo), nickel (Ni), titanium (Ti), chrome (Cr), or an alloy thereof, but is not limited thereto.

The buffer layer 111 can be disposed on the substrate 110, the first light shielding layer LS1, and the second light shielding layer LS2. The buffer layer 111 can reduce permeation of moisture or impurities through the substrate 110. The buffer layer 111 can be configured by a single layer or a double layer of silicon oxide (SiOx) or silicon nitride (SiNx), but is not limited thereto. However, the buffer layer 111 can be omitted depending on a type of substrate 110 or a type of transistor, but is not limited thereto.

The first driving transistor DT1 and the second driving transistor DT2 can be disposed on the buffer layer 111. The first driving transistor DT1can include a first active layer ACT1, a first gate electrode GE1, a first source electrode SE1, and a first drain electrode DE1. The second driving transistor DT2 can include a second active layer ACT2, a second gate electrode GE2, a second source electrode SE2, and a second drain electrode DE2.

The first active layer ACT1 of the first driving transistor DT1 and the second active layer ACT2 of the second driving transistor DT2 can be disposed on the buffer layer 111. The first active layer ACT1 and the second active layer ACT2 can be formed of a semiconductor material such as an oxide semiconductor, amorphous silicon, or polysilicon, but are not limited thereto.

The gate insulating layer 112 can be disposed on the first active layer ACT1 and the second active layer ACT2. The gate insulating layer 112 is an insulating layer which electrically insulates the first active layer ACT1 and the second active layer ACT2 from the first gate electrode GE1 and the second gate electrode GE2, respectively, and can be configured by a single layer or a double layer of silicon oxide (SiOx) or silicon nitride (SiNx), but is not limited thereto.

The first gate electrode GE1 of the first driving transistor DT1 and the second gate electrode GE2 of the second driving transistor DT2 can be disposed on the gate insulating layer 112. The first gate electrode GE1 and the second gate electrode GE2 can be configured by a conductive material, such as copper (Cu), aluminum (Al), molybdenum (Mo), nickel (Ni), titanium (Ti), chrome (Cr), or an alloy thereof, but is not limited thereto.

The first interlayer insulating layer 113a, the second interlayer insulating layer 113b, and the first passivation layer 114a can be disposed on the first gate electrode GE1 and the second gate electrode GE2. In the first interlayer insulating layer 113a, the second interlayer insulating layer 113b, and the first passivation layer 114a, contact holes through which the source electrode SE and the drain electrode DE are connected to the active layer ACT are formed. The first interlayer insulating layer 113a, the second interlayer insulating layer 113b, and the first passivation layer 114a are insulating layers for protecting configuration below the first interlayer insulating layer 113a, the second interlayer insulating layer 113b, and the first passivation layer 114a. The first interlayer insulating layer 113a, the second interlayer insulating layer 113b, and the first passivation layer 114a are configured by a single layer or a double layer of silicon oxide (SiOx) or silicon nitride (SiNx), but are not limited thereto.

On the first passivation layer 114a, the first source electrode SE1 and the first drain electrode DE1 which are electrically connected to the first active layer ACT1 and the second source electrode SE2 and the second drain electrode DE2 which are electrically connected to the second active layer ACT2 can be disposed. The first source electrode SE1, the first drain electrode DE1, the second source electrode SE2, and the second drain electrode DE2 can be configured by a conductive material, such as copper (Cu), aluminum (Al), molybdenum (Mo), nickel (Ni), titanium (Ti), chrome (Cr), or an alloy thereof, but are not limited thereto.

However, in the present disclosure, it is described that the first interlayer insulating layer 113a, the second interlayer insulating layer 113b, and the first passivation layer 114a, for example, a plurality of insulating layers is disposed between the first gate electrode GE1 and the second gate electrode GE2 and the first source electrode SE1, the first drain electrode DE1, the second source electrode SE2, and the second drain electrode DE2. However, only one insulating layer can be disposed between the first gate electrode GE1 and the second gate electrode GE2 and the first source electrode SE1, the first drain electrode DE1, the second source electrode SE2, and the second drain electrode DE2 and the present disclosure is not limited thereto.

The first capacitor C1 and the second capacitor C2 can be disposed on the gate insulating layer 112. The first capacitor C1 can include a 1-1-th capacitor electrode C1a and a 1-2-th capacitor electrode C1b. The second capacitor C2 can include a 2-1-th capacitor electrode C2a and a 2-2-th capacitor electrode C2b.

First, the 1-1-th capacitor electrode C1a and the 2-1-th capacitor electrode C2a can be disposed on the gate insulating layer 112. The 1-1-th capacitor electrode C1a is integrally formed with the first gate electrode GE1 of the first driving transistor DT1 and the 2-1-th capacitor electrode C2a is integrally formed with the second gate electrode GE2 of the second driving transistor DT2, but the present disclosure is not limited thereto.

The 1-2-th capacitor electrode C1b and the 2-2-th capacitor electrode C2b can be disposed on the first interlayer insulating layer 113a. The 1-2-th capacitor electrode C1b can be disposed so as to overlap the 1-1-th capacitor electrode C1a with the first interlayer insulating layer 113a therebetween. Therefore, the first capacitor C1 is connected to the first gate electrode GE1 of the first driving transistor DT1 to maintain a voltage of the first gate electrode GE1 of the first driving transistor DT1 for a predetermined period.

The 2-2-th capacitor electrode C2b can be disposed so as to overlap the 2-1-th capacitor electrode C2a with the first interlayer insulating layer 113a therebetween. Therefore, the second capacitor C2 is connected to the second gate electrode GE2 of the second driving transistor DT2 to maintain a voltage of the second gate electrode GE2 of the second driving transistor DT2 for a predetermined period.

The second passivation layer 114b can be disposed on the first driving transistor DT1 and the second driving transistor DT2. The second passivation layer 114b can protect the first driving transistor DT1 and the second driving transistor DT2 from permeation of moisture or impurities. For example, the second passivation layer 114b can be configured by a single layer or a double layer of silicon oxide (SiOx) or silicon nitride (SiNx), but is not limited thereto. However, the second passivation layer 114b can be omitted depending on a type of the substrate 110 or a type of transistor, but is not limited thereto.

The first planarization layer 115a can be disposed on the second passivation layer 114b. The first planarization layer 115a can planarize an upper portion of the substrate 110 on which the first driving transistor DT1 and the second driving transistor DT2 are disposed. The first planarization layer 115a can be configured by a single layer or a double layer, and for example, can be formed of photoresist or an acrylic-based organic material, but is not limited thereto.

A plurality of reflective electrodes RE which is spaced apart from each other can be disposed on the first planarization layer 115a. The plurality of reflective electrodes RE electrically connects the light emitting diode LED to the first driving transistor DT1 and the second driving transistor DT2 and can serve as a reflector which reflects light emitted from the light emitting diode LED toward the top of the light emitting diode LED. The plurality of reflective electrodes RE is formed of a conductive material having the excellent reflecting property to reflect light emitted from the light emitting diode LED toward the top of the light emitting diode LED. Therefore, the plurality of reflective electrodes RE can include various conductive layers in consideration of a light reflection efficiency and a resistance. For example, a reflective plate can use an opaque conductive layer, such as silver (Ag), aluminum (Al), molybdenum (Mo), titanium (Ti), or an alloy thereof, and a transparent conductive layer, such as indium tin oxide (ITO), but the structure and the material of the reflective electrode are not limited thereto.

The plurality of reflective electrodes RE can include a plurality of first reflective electrodes RE1 and a plurality of second reflective electrodes RE2. The plurality of first reflective electrodes RE1 can electrically connect the first driving transistor DT1 and the light emitting diode LED. The plurality of first reflective electrodes RE1 can be connected to the first source electrode SE1 or the second drain electrode DE2 of the first driving transistor DT1 through a contact hole formed in the second passivation layer 114b and the first planarization layer 115a. Further, the plurality of first reflective electrodes RE1 can be electrically connected to the 1-1-th electrodes 124a1 and 124b1 of the light emitting diode LED through the first connection electrode CE1. Therefore, the plurality of first reflective electrodes RE1 can electrically connect the first driving transistor DT1 and the 1-1-th electrodes 124a1 and 124b1 of the light emitting diode LED.

For example, the plurality of first reflective electrodes RE1 can be disposed in each of the plurality of sub pixels SP. Specifically, in the first sub pixel SP1, one first reflective electrode RE1 among the plurality of first reflective electrodes RE1 can be connected to the 1-1-th electrode 124a1 of the 1-1-th light emitting diode 120a and the 1-1-th electrode 124b1 of the 1-2-th light emitting diode 120b through the first connection electrode CE1. Accordingly, one first reflective electrode RE1 can connect the 1-1-th light emitting diode 120a and the 1-2-th light emitting diode 120b which emit the same color light to the same first driving transistor DT1.

In the second sub pixel SP2, another first reflective electrode RE1 can connect the 1-1-th electrode 134a1 of the 2-1-th light emitting diode 130a and the 1-1-th electrode 134b1 of the 2-2-th light emitting diode 130b through the first connection electrode CE1. Accordingly, another first reflective electrode RE1 can connect the 2-1-th light emitting diode 130a and the 2-2-th light emitting diode 130b which emit the same color light to the same first driving transistor DT1.

In the third sub pixel SP3, the third first reflective electrode RE1 can connect the 1-1-th electrode 144a1 of the 3-1-th light emitting diode 140a and the 1-1-th electrode 144b1 of the 3-2-th light emitting diode 140b through the first connection electrode CE1. Accordingly, the third first reflective electrode RE1 can connect the 3-1-th light emitting diode 140a and the 3-2-th light emitting diode 140b which emit the same color light to the same first driving transistor DT1.

The second reflective electrode RE2 can electrically connect the second driving transistor DT2 and the light emitting diode LED. The second reflective electrodes RE2 can be connected to the second source electrode SE2 or the second drain electrode DE2 of the second driving transistor DT2 through a contact hole formed in the second passivation layer 114b and the first planarization layer 115a. Further, the second reflective electrode RE2 can be electrically connected to 1-2-th electrodes 124a2 and 124b2 of the light emitting diode LED through the second connection electrode CE2. Therefore, the second reflective electrode RE2 can electrically connect the second driving transistor DT2 and the 1-2-th electrodes 124a2 and 124b2 of the light emitting diode LED.

For example, the plurality of second reflective electrodes RE2 can be disposed in each of the plurality of sub pixels SP. Specifically, in the first sub pixel SP1, one second reflective electrode RE2 among the plurality of second reflective electrodes RE2 can be connected to the 1-2-th electrode 124a2 of the 1-1-th light emitting diode 120a and the 1-2-th electrode 124b2 of the 1-2-th light emitting diode 120b through the second connection electrode CE2. Accordingly, one second reflective electrode RE2 can connect the 1-1-th light emitting diode 120a and the 1-2-th light emitting diode 120b which emit the same color light to the same second driving transistor DT2.

In the second sub pixel SP2, another second reflective electrode RE2 can connect the 1-2-th electrode 134a2 of the 2-1-th light emitting diode 130a and the 1-2-th electrode 134b2 of the 2-2-th light emitting diode 130b through the second connection electrode CE2. Accordingly, another second reflective electrode RE2 can connect the 2-1-th light emitting diode 130a and the 2-2-th light emitting diode 130b which emit the same color light to the same second driving transistor DT2.

In the third sub pixel SP3, the third second reflective electrode RE2 can connect the 1-2-th electrode 144a2 of the 3-1-th light emitting diode 140a and the 1-2-th electrode 144b2 of the 3-2-th light emitting diode 140b through the second connection electrode CE2. Accordingly, the third second reflective electrode RE2 can connect the 3-1-th light emitting diode 140a and the 3-2-th light emitting diode 140b which emit the same color light to the same second driving transistor DT2.

In other words, each of the light emitting diodes LED can be connected to both the first driving transistor DT1 and the second driving transistor DT2 through the plurality of first reflective electrodes RE1 and the plurality of second reflective electrodes RE2. In each sub pixel SP, the plurality of first reflective electrodes RE1 is connected to the 1-1-th electrodes 124a1, 124b1, 134a1, 134b1, 144a1, and 144b1 and the plurality of second reflective electrodes RE2 is connected to the 1-2-th electrodes 124a2, 124b2, 134a2, 134b2, 144a2, and 144b2.

In the meantime, the plurality of reflective electrodes RE can further include a third reflective electrode which electrically connects the power line and the light emitting diode LED.

The third passivation layer 114c can be disposed on the plurality of reflective electrodes RE and the first planarization layer 115a. The third passivation layer 114c can protect the plurality of reflective electrodes RE from the permeation of moisture or impurities. For example, the third passivation layer 114c can be configured by a single layer or a double layer of silicon oxide (SiOx) or silicon nitride (SiNx), but is not limited thereto.

The adhesive layer 116 can be disposed on the third passivation layer 114c. The adhesive layer 116 is formed on the front surface of the substrate 110 to fix the light emitting diode LED disposed on the adhesive layer 116. The adhesive layer 116 can be formed of a photo curable adhesive material which is cured by light. For example, the adhesive layer 116 can be formed of an acrylic-based material including a photoresist, but is not limited thereto.

The plurality of light emitting diodes LED can be disposed in each of the plurality of sub pixels SP on the adhesive layer 160. The plurality of light emitting diodes LED is elements which emit light by a current and can include light emitting diodes LED which emit red light, green light, and blue light and implement various colored light including white by a combination thereof. For example, the plurality of light emitting diodes LED can be light emitting diodes (LED) or a micro LEDs, but is not limited thereto.

The 1-1-th light emitting diode 120a can include a first semiconductor layer 121a, an emission layer 122a, a second semiconductor layer 123a, a 1-1-th electrode 124a1, a 1-2-th electrode 124a2, a second electrode 125a, and a passivation film 126a.

The first semiconductor layer 121a is disposed on the adhesive layer 116 and the second semiconductor layer 123a can be disposed on the first semiconductor layer 121a. The first semiconductor layer 121a and the second semiconductor layer 123a can be layers formed by doping n-type and p-type impurities into a specific material. For example, the first semiconductor layer 121a and the second semiconductor layer 123a can be layers doped with n-type and p-type impurities into a material such as gallium nitride (GaN), indium aluminum phosphide (InAlP), or gallium arsenide (GaAs). Further, the p-type impurity can be magnesium (Mg), zinc (Zn), and beryllium (Be), and the n-type impurity can be silicon (Si), germanium, and tin (Sn), but is not limited thereto.

A part of the first semiconductor layer 121a can be disposed to outwardly protrude from the second semiconductor layer 123a. A top surface of the first semiconductor layer 121a can be formed by a part overlapping a bottom surface of the second semiconductor layer 123a and a part disposed at an outside of the bottom surface of the second semiconductor layer 123a. The light emitting diode LED can be a lateral light emitting diode LED. However, sizes and shapes of the first semiconductor layer 121a and the second semiconductor layer 123a are modified in various forms, but are not limited thereto.

For example, referring to FIG. 4, the first semiconductor layer 121a can protrude outwardly from the second semiconductor layer 123a in some direction. The first semiconductor layer 121a can protrude to the outside of the second semiconductor layer 123a from both edges of the second semiconductor layer 123a. A part of the first semiconductor layer 121a can protrude outwardly from the second semiconductor layer 123a in a specific direction.

The emission layer 122a can be disposed between the first semiconductor layer 121a and the second semiconductor layer 123a. The emission layer 122a is supplied with holes and electrons from the first semiconductor layer 121a and the second semiconductor layer 123a to emit light.

The emission layer 122a can be formed by a single layer or a multi-quantum well (MQW) structure, and for example, can be formed of indium gallium nitride (InGaN) or gallium nitride (GaN), but is not limited thereto.

In one embodiment, a light emitting diode can comprise a plurality of first electrodes and a second electrode, for example comprise two first electrodes and a second electrode. For example, in the 1-1-th light emitting diode 120a of FIG. 3, the two first electrodes can be a 1-1-th electrode 124a1 and a 1-2-th electrode 124a2, respectively. In the 1-2-th light emitting diode 120b of FIG. 3, the two first electrodes can be a 1-1-th electrode 124b1 and a 1-2-th electrode 124b2, respectively. In the 2-1-th light emitting diode 130a of FIG. 3, the two first electrodes can be a 1-1-th electrode 134a1 and a 1-2-th electrode 134a2, respectively. In the 2-2-th light emitting diode 130b of FIG. 3, the two first electrodes can be a 1-1-th electrode 134b1 and a 1-2-th electrode 134b2, respectively. In the 3-1-th light emitting diode 140a of FIG. 3, the two first electrodes can be a 1-1-th electrode 144a1 and a 1-2-th electrode 144a2, respectively. In the 3-2-th light emitting diode 140b of FIG. 3, the two first electrodes can be a 1-1-th electrode 144b1 and a 1-2-th electrode 144b2, respectively. However, the present disclosure is not limited thereto, and the number of the first electrodes and the number of the second electrode included in a light emitting diode can be other number as desired. As shown in FIG. 4, The first electrode 124a can be disposed on the first semiconductor layer 121a. The 1-1-th electrode 124a1 and the 1-2-th electrode 124a2 are electrodes for electrically connecting the driving transistor DT and the first semiconductor layer 121a. In this case, the first semiconductor layer 121a is a semiconductor layer doped with an n-type impurity and the 1-1-th electrode 124a1 and the 1-2-th electrode 124a2 can be cathodes. In the meantime, the first electrode can include the 1-1-th electrode 124a1 and the 1-2-th electrode 124a2. Therefore, the 1-1-th electrode 124a1 and the 1-2-th electrode 124a2 can be referred to as a first n-type electrode and a second n-type electrode, but are not limited thereto. The 1-1-th electrode 124a1 and the 1-2-th electrode 124a2 can be disposed on a top surface of the first semiconductor layer 121a which is exposed from the emission layer 122a and the second semiconductor layer 123a. For example, the first electrode 124 is disposed on both end portions of the first semiconductor layer 121a to have a truncated oval shape. The 1-1-th electrode 124a1 and the 1-2-th electrode 124a2 can be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but are not limited thereto.

In the meantime, the 1-1-th electrode 124a1 and the 1-2-th electrode 124a2 can be connected to different driving transistors DT. For example, the 1-1-th electrode 124a1 is connected to the first driving transistor DT1 and the 1-2-th electrode 124a2 can be connected to the second driving transistor DT2.

The second electrode 125a can be disposed on the second semiconductor layer 123a. The second electrode 125a can be disposed on the top surface of the second semiconductor layer 123a. At this time, the second semiconductor layer 123a is disposed on the first semiconductor layer 121a so that the second electrode 125a disposed on the top surface of the second semiconductor layer 123a can be disposed to be higher than the first electrode 124a disposed on the top surface of the first semiconductor layer 121a. The second electrode 125a is an electrode for electrically connecting the power line and the second semiconductor layer 123a. In this case, the second semiconductor layer 123a is a semiconductor layer doped with a p-type impurity and the second electrode 125a can be an anode. The second electrode 125 can be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

Next, the passivation film 126a which encloses the first semiconductor layer 121a, the emission layer 122a, the second semiconductor layer 123a, the first electrode 124a, and the second electrode 125a can be disposed. The passivation film 126a is formed of an insulating material to protect the first semiconductor layer 121a, the emission layer 122a, and the second semiconductor layer 123a. Further, in the passivation film 126a, a contact hole which exposes the 1-1-th electrode 124a1, the 1-2-th electrode 124a2, and the second electrode 125a is formed to electrically connect the first connection electrode CE1, the second connection electrode CE2, and the third connection electrode CE3 which will be formed thereafter to the 1-1-th electrode 124a1, the 1-2-th electrode 124a2, and the second electrode 125a.

In the meantime, the placement of the 1-2-th light emitting diode 120b, the 2-1-th light emitting diode 130a, the 2-2-th light emitting diode 130b, the 3-1-th light emitting diode 140a, and the 3-2-th light emitting diode 140b can be substantially the same as the placement of the 1-1-th light emitting diode 120a.

For example, in FIG. 4, the cross-section regarding the 1-1-th light emitting diode 120a has been illustrated. However, a 1-2-th light emitting diode 120b, a 2-1-th light emitting diode 130a, a 2-2-th light emitting diode 130b, a 3-1-th light emitting diode 140a, and a 3-2-th light emitting diode 140b are also electrically connected to another component (for example, the first driving transistor DT1 and the second driving transistor DT2) in the same manner as the 1-1-th light emitting diode 120a. A redundant description will be omitted or may be briefly provided.

The second planarization layer 115b and the third planarization layer 115c can be disposed on the adhesive layer 116. The second planarization layer 115b and the third planarization layer 115c are disposed so as to enclose a part of side surfaces of the plurality of light emitting diodes LED to fix and protect the plurality of light emitting diodes LED. The third planarization layer 115c is formed to cover upper portions of the second planarization layer 115b and the light emitting diode LED and a contact hole which exposes the first electrodes 124a and 124b and the second electrodes 125a and 125b of the light emitting diode LED can be formed. Accordingly, the first electrodes 124a and 124b and the second electrodes 125a and 125b of the light emitting diode 120 are exposed from the third planarization layer 115c and the third planarization layer 115c is partially disposed in an area between the first electrodes 124a and 124b and the second electrodes 125a and 125b to reduce a short-circuit defect. The second planarization layer 115b and the third planarization layer 115c can be configured by a single layer or a double layer, and for example, can be formed of photoresist or an acrylic-based organic material, but is not limited thereto.

The first connection electrode CE1, the second connection electrode CE2, and the third connection electrode CE3 can be disposed on the third planarization layer 115c. The first connection electrode CE1 is an electrode which is disposed in each of the plurality of sub pixels SP to electrically connect the light emitting diode LED and the first driving transistor DT1. The first connection electrode CE1 can be connected to the first reflective electrode RE1 through the contact holes formed in the third planarization layer 115c, the second planarization layer 115b, the third passivation layer 114c, and the adhesive layer 116. Accordingly, the first connection electrode CE1 can be electrically connected to any one of the first source electrode SE1 and the first drain electrode DE1 of the first driving transistor DT1 through the first reflective electrode RE1. For example, the first connection electrode CE1 can connect the 1-1-th electrodes 124a1 and 124b1 of two light emitting diodes LED which emit the same color light to the first source electrode SE1 of the first driving transistor DT1, but is not limited thereto.

For example, the first connection electrodes CE1 can be disposed in each of the plurality of sub pixels SP. Specifically, in the first sub pixel SP1, any one of the first connection electrodes CE1 can connect the 1-1-th electrode 124a1 of the 1-1-th light emitting diode 120a and the 1-1-th electrode 124b1 of the 1-2-th light emitting diode 120b to the first source electrode SE1 of the first driving transistor DT1. In the second sub pixel SP2, another first connection electrode CE1 can connect the 1-1-th electrode 134a1 of the 2-1-th light emitting diode 130a and the 1-1-th electrode 134b1 of the 2-2-th light emitting diode 130b to the first source electrode SE1 of the first driving transistor DT1. In the third sub pixel SP3, the third first connection electrode CE1 can connect the 1-1-th electrode 144a1 of the 3-1-th light emitting diode 140a and the 1-1-th electrode 144b1 of the 3-2-th light emitting diode 140b to the first source electrode SE1 of the first driving transistor DT1.

In other words, two light emitting diodes LED which emit the same color light can share the first connection electrode CE1. For example, the first connection electrodes CE1 disposed in the first sub pixel SP1 is connected to both the 1-1-th electrode 124a1 of the 1-1-th light emitting diode 120a and the 1-1-th electrode 124b1 of the 1-2-th light emitting diode 120b to connect the 1-1-th light emitting diode 120a and the 1-2-th light emitting diode 120b to the first driving transistor DT1. Further, the first connection electrodes CE1 disposed in the second sub pixel SP2 is connected to both the 1-1-th electrode 134a1 of the 2-1-th light emitting diode 130a and the 1-1-th electrode 134b1 of the 2-2-th light emitting diode 130b to connect the 2-1-th light emitting diode 130a and the 2-2-th light emitting diode 130b to the first driving transistor DT1. Likewise, the first connection electrodes CE1 disposed in the third sub pixel SP3 is connected to both the 1-1-th electrode 144a1 of the 3-1-th light emitting diode 140a and the 1-1-th electrode 144b1 of the 3-2-th light emitting diode 140b to connect the 3-1-th light emitting diode 140a and the 3-2-th light emitting diode 140b to the first driving transistor DT1.

For example, the first connection electrode CE1 can be formed of a conductive material, for example, a transparent conductive material, such as indium tin oxide (ITO) or indium zinc oxide (IZO), but is not limited thereto.

The second connection electrode CE2 is an electrode which is disposed in the light emitting diode LED and each of the plurality of sub pixels SP to electrically connect the light emitting diode LED and the second driving transistor DT2. The second connection electrode CE2 can be connected to the second reflective electrode RE2 through the contact holes formed in the third planarization layer 115c, the second planarization layer 115b, the third passivation layer 114c, and the adhesive layer 116. Accordingly, the second connection electrode CE2 can be electrically connected to any one of the second source electrode SE2 and the second drain electrode DE2 of the second driving transistor DT2 through the second reflective electrode RE2. For example, the second connection electrode CE2 connects the 1-2-th electrodes 124a2 and 124b2 of the light emitting diode LED to the second source electrode SE2 of the second driving transistor DT2, but it is not limited thereto.

For example, the second connection electrodes CE2 can be disposed in each of the plurality of sub pixels SP. Specifically, in the first sub pixel SP1, any one of the second connection electrodes CE2 connects the 1-2-th electrode 124a2 of the 1-1-th light emitting diode 120a and the 1-2-th electrode 124b2 of the 1-2-th light emitting diode 120b to the second source electrode SE2 of the second driving transistor DT2. In the second sub pixel SP2, another second connection electrode CE2 connects the 1-2-th electrode 134a2 of the 2-1-th light emitting diode 130a and the 1-2-th electrode 134b2 of the 2-2-th light emitting diode 130b to the second source electrode SE2 of the second driving transistor DT2. In the third sub pixel SP3, the third second connection electrode CE2 connects the 1-2-th electrode 144a2 of the 3-1-th light emitting diode 140a and the 1-2-th electrode 144b2 of the 3-2-th light emitting diode 140b to the second source electrode SE2 of the second driving transistor DT2.

In other words, two light emitting diodes LED which emit the same color light can share the second connection electrode CE2. For example, the second connection electrodes CE2 disposed in the first sub pixel SP1 is connected to both the 1-2-th electrode 124a2 of the 1-1-th light emitting diode 120a and the 1-2-th electrode 124b2 of the 1-2-th light emitting diode 120b to connect the 1-1-th light emitting diode 120a and the 1-2-th light emitting diode 120b to the second driving transistor DT2. Further, the second connection electrodes CE2 disposed in the second sub pixel SP2 is connected to both the 1-2-th electrode 134a2 of the 2-1-th light emitting diode 130a and the 1-2-th electrode 134b2 of the 2-2-th light emitting diode 130b to connect the 2-1-th light emitting diode 130a and the 2-2-th light emitting diode 130b to the second driving transistor DT2. Likewise, the second connection electrodes CE2 disposed in the third sub pixel SP3 is connected to both the 1-2-th electrode 144a2 of the 3-1-th light emitting diode 140a and the 1-2-th electrode 144b2 of the 3-2-th light emitting diode 140b to connect the 3-1-th light emitting diode 140a and the 3-2-th light emitting diode 140b to the second driving transistor DT2.

In the meantime, the second connection electrode CE2 is disposed on the same layer as the first connection electrode CE1 to be formed of the same material, but is not limited thereto. The second connection electrode CE2 can be formed of a conductive material, for example, a transparent conductive material, such as indium tin oxide (ITO) or indium zinc oxide (IZO), but is not limited thereto.

The third connection electrode CE3 is an electrode for electrically connecting the light emitting diode LED and the power line. For example, the third connection electrode CE3 can electrically connect a high potential power line which applies a high potential power voltage to the second electrodes 125a, 125b, 135a, 135b, 145a, and 145b of the light emitting diode LED, but is not limited thereto. The third connection electrode CE3 is disposed on the same layer as the first connection electrode CE1 and the second connection electrode CE2 to be formed of the same material, but is not limited thereto. For example, the third connection electrode CE3 can be formed of a conductive material, for example, a transparent conductive material, such as indium tin oxide (ITO) or indium zinc oxide (IZO), but is not limited thereto.

For example, the third connection electrodes CE3 can be commonly disposed in the plurality of sub pixels SP. In other words, the first sub pixel SP1, the second sub pixel SP2, and the third sub pixel SP3 share the third connection electrode CE3, but are not limited thereto.

The bank 117 can be disposed on the third planarization layer 115c, the first connection electrode CE1, the second connection electrode CE2, and the third connection electrode CE3. The bank 117 is disposed so as not to overlap the light emitting diode LED to define an emission area. For example, the bank 117 covers edges of the first connection electrode CE1 and the second connection electrode CE2 which are connected to the light emitting diodes LED to define the emission area. For example, the bank 117 can divide the plurality of sub pixels SP. The bank 117 can be formed of an insulating material to insulate the first connection electrode CE1 and the second connection electrodes CE2 of adjacent sub pixels SP from each other. Further, the bank 117 can include a black component having high light absorptivity or can be configured by a black bank to suppress color mixture between adjacent sub pixels SP. The bank 117 can be formed of a polyimide resin, an acrylic resin, or a benzocyclobutene (BCB) resin, but is not limited thereto.

The capping layer 118 can be disposed on the third planarization layer 115c, the first connection electrode CE1, the second connection electrode CE2, the third connection electrode CE3, and the bank 117. The capping layer 118 is disposed so as to cover the top surface of the light emitting diode LED to planarize the upper portion of the substrate 110 on which the light emitting diode LED is disposed and fix and protect the light emitting diode LED. Therefore, the capping layer 118 can be referred to as a protection layer or a fourth planarization layer, but is not limited thereto. The capping layer 118 can be configured by a single layer or a double layer, and for example, can be formed of photoresist or an acrylic-based organic material, but is not limited thereto.

In the display device, a defective sub pixel which does not normally emit light can occur. For example, when the light emitting diode itself is defective or the light emitting diode is normal, but a driving transistor connected to the light emitting diode is defective, the corresponding sub pixel can become a defective sub pixel. Therefore, in order to prepare for the occurrence of a defective sub pixel, an additional sub pixel which emits the same light as each of the plurality of sub pixels can be disposed. For example, in order to prepare for the occurrence of a defective sub pixel due to the defect of the light emitting diode, two light emitting diodes which emit the same color light can be disposed. In this case, even though any one of light emitting diodes is defective, the other one is lit up to minimize the defect that the sub pixel completely becomes a dark spot. However, if two light emitting diodes are connected to the same driving transistor in parallel, even though two light emitting diodes are normal, the two light emitting diodes may not be lit up due to the defect of the driving transistor. Therefore, the driving transistors can be disposed as many as the number of light emitting diodes to individually connect the light emitting diodes to the driving transistors. However, also in this case, if the driving transistor itself is defective, there was a problem in that the light emitting diode connected to the defective driving transistor is not lit up.

Accordingly, in the display device 100 according to the example embodiment of the present disclosure, the light emitting diode LED is connected to two driving transistors DT so that even though any one of the driving transistors DT is defective, the light emitting diode LED is lit up by the other driving transistor. For example, the light emitting diode LED can include two first electrodes 124a, 124b, 134a, 134b, 144a, and 144b. At this time, two first electrodes 124a, 124b, 134a, 134b, 144a, and 144b can be connected to different driving transistors DT. Specifically, the 1-1-th electrodes 124a1, 124b1, 134a1, 134b1, 144a1, and 144b1 of the light emitting diode LED are connected to the first driving transistor DT1 and the 1-2-th electrodes 124a2, 124b2, 134a2, 134b2, 144a2, and 144b2 can be connected to the second driving transistors DT2. Accordingly, even though the first driving transistor DT1 is defective, the light emitting diode LED can be lit up through the second driving transistor DT2. Likewise, even though the second driving transistor DT2 is defective, the light emitting diode LED can be lit up through the first driving transistor DT1. Therefore, the problem in that the light emitting diode LED is not lit up due to the defect of the driving transistor DT can be minimized or prevented. As a result, a defect that the sub pixel SP in which the defective driving transistor is disposed becomes a dark spot can be improved.

Further, in the display device 100 according to the example embodiment of the present disclosure, two light emitting diodes LED which emit the same color light can be disposed in one sub pixel SP. At this time, two light emitting diodes LED can share the first driving transistor DT1 and the second driving transistor DT2. For example, the first driving transistor DT1 and the second driving transistor DT2 can be connected to both two light emitting diodes LED which emit the same color. Accordingly, even though the first driving transistor DT1 is defective, two light emitting diodes LED can be simultaneously lit up through the second driving transistor DT2. Likewise, even though the second driving transistor DT2 is defective, two light emitting diodes LED can be simultaneously lit up through the first driving transistor DT1. Therefore, the problem in that the light emitting diode LED is not lit up due to the defect of the driving transistor DT can be minimized or prevented. As a result, a defect that the sub pixel SP in which the defective driving transistor is disposed becomes a dark spot can be improved. Further, in the display device 100 according to the example embodiment of the present disclosure, two light emitting diodes LED are simultaneously lit up so that a high luminance can be implemented as compared with a case that only one light emitting diode LED is lit up.

The example embodiments of the present disclosure can also be described as follows:

According to an aspect of the present disclosure, there is provided a display device. The display device includes a substrate, a first sub pixel circuit which is disposed on the substrate and includes a first driving transistor, a second sub pixel circuit which is disposed on the substrate and includes a second driving transistor and a plurality of light emitting diodes which is disposed on the first sub pixel circuit and the second sub pixel circuit and includes a plurality of first electrodes and a second electrode. Any one of the plurality of first electrodes is electrically connected to the first driving transistor and the other one of the plurality of first electrodes is electrically connected to the second driving transistor.

The plurality of light emitting diodes can include a first light emitting diode and a second light emitting diode which emit same color light, and the first light emitting diode and the second light emitting diode can share the first driving transistor and the second driving transistor.

Any one of the plurality of first electrodes of the first light emitting diode and any one of the plurality of first electrodes of the second light emitting diode can electrically connected to the first driving transistor and the other one of the plurality of first electrodes of the first light emitting diode and the other one of the plurality of first electrodes of the second light emitting diode can be electrically connected to the second driving transistor.

The display device can further include a first reflective electrode which is disposed between the first driving transistor and the plurality of light emitting diodes to electrically connect the first driving transistor and any one of the plurality of first electrodes and a second reflective electrode which is disposed between the second driving transistor and the plurality of light emitting diodes to electrically connect the second driving transistor and the other one of the plurality of first electrodes.

The display device can further include a first connection electrode which electrically connects the first driving transistor and any one of the plurality of first electrodes through the first reflective electrode and a second connection electrode which electrically connects the second driving transistor and the other one of the plurality of first electrodes through the second reflective electrode. The plurality of light emitting diodes can include a first light emitting diode and a second light emitting diode which emit same color light. The first light emitting diode and the second light emitting diode can share the first connection electrode and the second connection electrode.

The first connection electrode can electrically connect the first driving transistor and any one of the plurality of first electrodes of the first light emitting diode and any one of the plurality of first electrodes of the second light emitting diode, and the second connection electrode can electrically connect the second driving transistor and the other one of the plurality of first electrodes of the first light emitting diode and the other one of the plurality of first electrodes of the second light emitting diode.

The display device can further include a scan line, a data line, and a reference line disposed on the substrate. The first sub pixel circuit and the second sub pixel circuit can share the scan line, the data line, and the reference line.

The first sub pixel circuit can further include a first switching transistor and a first sensing transistor. The second sub pixel circuit can further include a second switching transistor and a second sensing transistor. The first switching transistor and the second switching transistor can be electrically connected to the scan line and the data line and the first sensing transistor and the second sensing transistor can be electrically connected to the scan line and the reference line.

According to another aspect of the present disclosure, there is provided a display device. The display device includes a substrate in which a plurality of sub pixels is defined, a first driving transistor and a second driving transistor which are disposed on the substrate in each of the plurality of sub pixels, a first light emitting diode and a second light emitting diode which are disposed on the first driving transistor and the second driving transistor in each of the plurality of sub pixels and emit the same color light. Each of the first driving transistor and the second driving transistor is electrically connected to both the first light emitting diode and the second light emitting diode.

Each of the first light emitting diode and the second light emitting diode can include a 1-1-th electrode, 1-2-th electrode, and a second electrode, the 1-1-th electrode can be electrically connected to the first driving transistor, and the 1-2-th electrode can be electrically connected to the second driving transistor.

The display device can further include a first connection electrode which electrically connects the first driving transistor and the 1-1-th electrode and a second connection electrode which electrically connects the second driving transistor and the 1-2-th electrode.

The display device can further include a first reflective electrode which is disposed between the first driving transistor and the first light emitting diode or the second light emitting diode to electrically connect the first driving transistor and the 1-1-th electrode of the first light emitting diode or the second light emitting diode and a second reflective electrode which is disposed between the second driving transistor and the first light emitting diode or the second light emitting diode to electrically connect the second driving transistor and the 1-2-th electrode of the first light emitting diode or the second light emitting diode.

The first connection electrode can electrically connect the first driving transistor and the 1-1-th electrode of the first light emitting diode and the 1-1-th electrode of the second light emitting diode and the second connection electrode can electrically connect the second driving transistor and the 1-2-th electrode of the first light emitting diode and the 1-2-th electrode of the second light emitting diode.

The first light emitting diode and the second light emitting diode can share the first connection electrode and the second connection electrode.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display device comprising:
a substrate;
a first sub pixel circuit which is disposed on the substrate and includes a first driving transistor;
a second sub pixel circuit which is disposed on the substrate and includes a second driving transistor; and
a plurality of light emitting diodes which is disposed on the first sub pixel circuit and the second sub pixel circuit, and includes a plurality of first electrodes and a second electrode,
wherein any one of the plurality of first electrodes is electrically connected to the first driving transistor and another one of the plurality of first electrodes is electrically connected to the second driving transistor.

2. The display device according to claim 1, wherein the plurality of light emitting diodes includes a first light emitting diode and a second light emitting diode which are configured to emit a same color light, and
wherein the first light emitting diode and the second light emitting diode share the first driving transistor and the second driving transistor.

3. The display device according to claim 2, wherein any one of the plurality of first electrodes of the first light emitting diode and any one of the plurality of first electrodes of the second light emitting diode are electrically connected to the first driving transistor, and
wherein another one of the plurality of first electrodes of the first light emitting diode and another one of the plurality of first electrodes of the second light emitting diode are electrically connected to the second driving transistor.

4. The display device according to claim 1, further comprising:
a first reflective electrode which is disposed between the first driving transistor and the plurality of light emitting diodes to electrically connect the first driving transistor and any one of the plurality of first electrodes; and
a second reflective electrode which is disposed between the second driving transistor and the plurality of light emitting diodes to electrically connect the second driving transistor and another one of the plurality of first electrodes.

5. The display device according to claim 4, further comprising:
a first connection electrode which electrically connects the first driving transistor and any one of the plurality of first electrodes through the first reflective electrode; and
a second connection electrode which electrically connects the second driving transistor and another one of the plurality of first electrodes through the second reflective electrode.

6. The display device according to claim 5, wherein the plurality of light emitting diodes includes a first light emitting diode and a second light emitting diode which are configured to emit a same color light, and
wherein the first light emitting diode and the second light emitting diode share the first connection electrode and the second connection electrode.

7. The display device according to claim 6, wherein the first connection electrode electrically connects the first driving transistor and any one of the plurality of first electrodes of the first light emitting diode and any one of the plurality of first electrodes of the second light emitting diode, and
wherein the second connection electrode electrically connects the second driving transistor and another one of the plurality of first electrodes of the first light emitting diode and another one of the plurality of first electrodes of the second light emitting diode.

8. The display device according to claim 1, further comprising:
a scan line, a data line, and a reference line disposed on the substrate,
wherein the first sub pixel circuit and the second sub pixel circuit share the scan line, the data line, and the reference line.

9. The display device according to claim 8, wherein the first sub pixel circuit further includes a first switching transistor and a first sensing transistor,
wherein the second sub pixel circuit further includes a second switching transistor and a second sensing transistor, and
wherein the first switching transistor and the second switching transistor are electrically connected to the scan line and the data line, and the first sensing transistor and the second sensing transistor are electrically connected to the scan line and the reference line.

10. A display device comprising:
a substrate in which a plurality of sub pixels is defined;
a first driving transistor and a second driving transistor which are disposed on the substrate in each of the plurality of sub pixels; and
a first light emitting diode and a second light emitting diode which are disposed on the first driving transistor and the second driving transistor in each of the plurality of sub pixels and are configured to emit a same color light,
wherein each of the first driving transistor and the second driving transistor is electrically connected to both the first light emitting diode and the second light emitting diode.

11. The display device according to claim 10, wherein each of the first light emitting diode and the second light emitting diode includes a 1-1-th electrode, a 1-2-th electrode, and a second electrode, and
wherein the 1-1-th electrode is electrically connected to the first driving transistor, and the 1-2-th electrode is electrically connected to the second driving transistor.

12. The display device according to claim 11, further comprising:
a first connection electrode which electrically connects the first driving transistor and the 1-1-th electrode; and
a second connection electrode which electrically connects the second driving transistor and the 1-2-th electrode.

13. The display device according to claim 11, further comprising:
a first reflective electrode which is disposed between the first driving transistor and one of the first and second light emitting diodes to electrically connect the first driving transistor and the 1-1-th electrode of one of the first and second light emitting diodes; and
a second reflective electrode which is disposed between the second driving transistor and one of the first and second light emitting diodes to electrically connect the second driving transistor and the 1-2-th electrode of one of the first and second light emitting diodes.

14. The display device according to claim 12, wherein the first connection electrode electrically connects the first driving transistor and the 1-1-th electrode of the first light emitting diode and the 1-1-th electrode of the second light emitting diode, and
wherein the second connection electrode electrically connects the second driving transistor and the 1-2-th electrode of the first light emitting diode and the 1-2-th electrode of the second light emitting diode.

15. The display device according to claim 12, wherein the first light emitting diode and the second light emitting diode share the first connection electrode and the second connection electrode.

16. The display device according to claim 10, wherein a shape of the first light emitting diode and a shape of the second light emitting diode in each of the plurality of sub pixels are the same.

17. The display device according to claim 10, wherein the first and second light emitting diodes in each of the plurality of sub pixels are configured to emit a same color light.

18. The display device according to claim 10, further comprising:
a first reflective electrode disposed between the first driving transistor and the first and second light emitting diodes; and
a second reflective electrode between the second driving transistor and the first and second light emitting diodes.
